(19) United States
(12) Patent Application Publication
(10) Pub. No.: US 2002/0178422 A1
(43) Pub. Date: Nov. 28, 2002

(54) Method and apparatus for implementing a time varying trellis

(75) Inventors: Richard L. Galbraith, Rochester, MN (US); Allen P. Haar, Essex Junction, VT (US); David J. Stanek, Rochester, MN (US)

Correspondence Address: ARLEN L. OLSEN, SCHMEISER, OLSEN & WATTS, 3 LEAR JET LANE, SUITE 201, LATHAM, NY, 12110, US

(73) Assignee: International Business Machines Corporation, Armonk, NY (US)

(21) Appl. No.: 09/833,141

(22) Filed: Apr. 11, 2001

(51) Int. Cl. H03M 13/03

(52) U.S. Cl. 714/794; 714/795

(57) ABSTRACT

A method and apparatus for maximum likelihood detection of a sequential stream of binary bits. 2^{N} binary states (N≧2) are projected onto a trellis at a sequence of times. Two branches to each binary state at time Tᵢ₊₁ from a closest previous time Tᵢ are identified (i≧N). There are 2^{N+1} such branches between Tᵢ and Tᵢ₊₁. A state metric for each of the 2^{N} binary states at Tᵢ and a branch metric for each of the 2^{N+1} branches between Tᵢ and Tᵢ₊₁ are provided. An illegal branch and a legal branch to a state S1 at time Tᵢ₊₁ are so designated. A state metric is computed at each of the 2^{N} binary states at time Tᵢ₊₁ as a function of: the state metrics at Tᵢ, the branch metrics between Tᵢ and Tᵢ₊₁, and the 2 branches to state S1.

### BACKGROUND OF THE INVENTION

1. Technical Field

The present invention relates to a method and apparatus for maximum likelihood detection in relation to a time varying viterbi trellis.

2. Related Art

In various technologies, (e.g., magnetic recording, hard disk data storage, CD-ROM data storage, cell phones, etc.), sequential data streams of binary bits are written to a magnetic medium. The data streams may be read or played back to confirm that the played-back sequence is the same as the originally written sequence. As the binary bits are played back, a measurement (e.g., a differential voltage measurement) may be made at each time that a next binary bit is read. In principle, such measurements enable a determination of the exact sequence of the played-back binary bits. However, the played-back binary bit sequence is subject to error such as intersymbol interference (effect of a played-back bit on the value of a subsequent played-back bit) and Guassian white noise. Due to such error, the played-back sequence of binary bits cannot be ascertained deterministically. Probabilistic or statistical methods are thus more appropriate. Unfortunately, the statistical errors associated with known probabilistic or statistical methods may be large or otherwise unacceptable. Therefore, there is a need for a method and apparatus that more accurately detects a played-back sequence of binary bits with little increase in hardware complexity and negligible change in computation speed.

### SUMMARY OF THE INVENTION

The present invention provides a method for maximum likelihood detection of a sequential stream of binary bits, comprising:

providing a trellis onto which 2^{N} binary states are projected at each discrete time of a sequence of times, said N≧2;

identifying, for each of the 2^{N} binary states at time Tᵢ₊₁, 2 branches to each of the 2^{N} binary states at time Tᵢ₊₁ from a closest previous time Tᵢ for a total of 2^{N+}such branches between Tᵢ; and Tᵢ₊₁, said i≧N or i≧1;

providing a state metric for each of the 2^{N} binary states at Tᵢ and a branch metric for each of the 2^{N+1} branches between Tᵢ and Tᵢ₊₁;

designating a first illegal branch of said 2 branches to a state S1 at time Tᵢ₊₁;

selecting another branch of said 2 branches to the state S1 from the group consisting of a second illegal branch and a paralegal branch; and

computing a state metric at each of the 2^{N} binary states at time Tᵢ₊₁, said state metrics at Tᵢ₊₁ being functionally dependent upon: said state metrics at Tᵢ, said branch metrics between Tᵢ and Tᵢ₊₁, and said 2 branches to state S1.

The present invention provides a maximum likelihood detection trellis structure, comprising:

a trellis onto which 2^{N} binary states have been mapped at each discrete time of a sequence of times, said N≧2;

2 branches to each of the 2^{N} binary states at time Tᵢ₊₁ from a closest previous time Tᵢ for a total of 2^{N+1} such branches between Tᵢ and Tᵢ₊₁, said i≧N or i≧1;

a first illegal branch of said 2 branches to a state S1 at time Tᵢ₊₁; and

another branch of said 2 branches to the state S1, said another branch selected from the group consisting of a second illegal branch and a paralegal branch.

The present invention provides an Illegal Branch Exclusion method for calculating a state metric ST_Z of an output state Z given input states X and Y, the method comprising:

providing a state metric ST_X of the input state X and a branch metric BR_X_Z of a branch X→Z from the input state X to the output state Z;

providing a state metric ST_Y of the input state Y and a branch metric BR_Y_Z of a branch Y→Z from the input state Y to the output state Z, said X→Z and Y→Z are both legal or one of said X→Z and Y→Z is illegal and the other of said X→Z and Y→Z is paralegal;

defining A=ST_X+BR_X_Z, B=ST_Y+BR_Y_Z, and a relational condition selected from the group consisting of A>B and A<B; and

calculating ST_Z such that: if X→Z and Y→Z are both legal then said calculating ST_Z is according to ST_Z=B if the relational condition is true or ST_Z=A if the relational condition is false, if X→Z is illegal then said calculating ST_Z is according to ST_Z=B, if Y→Z is illegal then said calculating ST_Z is according to ST_Z=A.

The present invention provides a Large State Metric Value method for calculating a state metric ST_Z of an output state Z given input states X and Y, the method comprising:

providing a state metric ST_X of the input state X and a branch metric BR_X_Z of a branch X→Z from the input state X to the output state Z;

providing a state metric ST_Y of the input state Y and a branch metric BR_Y_Z of a branch Y→Z from the input state Y to the output state Z, said X→Z and Y→Z are both legal or said X→Z and Y→Z are both illegal;

defining A=ST_X+BR_X_Z, B=ST_Y+BR_Y_Z, and a relational condition selected from the group consisting of A>B and A<B; and

calculating ST_Z such that: if X→Z and Y→Z are both legal then said calculating ST_Z is according to ST_Z=B if the relational condition is true or ST_Z=A if the relational condition is false, if X→Z and Y→Z are both illegal then said calculating ST_Z is according to ST_Z=LSMV, said LSMV being positive and sufficiently large if the relational condition is A>B or said LSMV being negative and sufficiently large if the relational condition is A<B.

The present invention provides a TVT_M2M2 apparatus configured to calculate a state metric ST_Z of an output state Z given input states X and Y, comprising:

an adder configured to compute A and B, said A=ST_X+BR_X_Z, said ST_X being a state metric of the input state X, said BR_X_Z being a branch metric of a branch X→Z from the input state X to the output state Z, said B=ST_Y+BR_Y_Z, said ST_Y being a state metric of the input state Y, said BR_Y_Z being a branch metric of a branch Y→Z from the input state Y to the output state Z, said X→Z and Y→Z are both legal or one of said X→Z and Y→Z is illegal and the other of said X→Z and Y→Z is paralegal;

a comparator configured to receive A and B from said adder, said comparator configured to compare A and B to ascertain whether a relational condition is true, said comparator configured to generate a comparator output of 1 if the relational condition is true or to generate the comparator output of 0 if the relational condition is false, said relational condition being selected from the group consisting of A>B and A<B;

a first multiplexor (MUX1) having input ports D0 and D1 and select input SEL1, said D0 configured to receive the comparator output, said D1 configured to receive 0 if said Y→Z is illegal, said D1 configured to receive 1 if said X→Z illegal, said SEL1 configured to be set to 0 if said X→Z and Y→Z are both legal, said SEL1 configured to be set to 1 if one of said X→Z and Y→Z is illegal and the other of said X→Z and Y→Z is paralegal, if SEL1=0 said MUX1 configured to select D0, if SEL1=1 said MUX1 configured to select D1, said MUX1 configured to generate a MUX1 output of what the MUX1 has selected; and

a second multiplexor (MUX2) having input ports E0 and E1 and select input SEL2, said E0 configured to receive A from the adder, said E1 configured to receive B from the adder, set SEL2 configured to receive the MUX1 output, if SEL2=0 then said MUX2 configured to select E0, if SEL2=1 then said MUX2 configured to select E1, said MUX2 configured to generate a MUX2 output of what the MUX2 has selected, said ST_Z=said MUX2 output.

The present invention provides a TVT_M3 apparatus configured to calculate a state metric ST_Z of an output state Z given input states X and Y, comprising:

an adder configured to compute A and B, said A=ST_X+BR_X_Z, said ST_X being a state metric of the input state X, said BR_X_Z being a branch metric of a branch X→Z from the input state X to the output state Z, said B=ST_Y+BR_Y_Z, said ST_Y being a state metric of the input state Y, said BR_Y_Z being a branch metric of a branch Y→Z from the input state Y to the output state Z, said X→Z and Y→Z both legal or said X→Z and Y→Z both illegal;

a comparator configured to receive A and B from said adder, said comparator configured to compare A and B to ascertain whether a relational condition is true, said comparator configured to generate a comparator output of 1 if the relational condition is true or the comparator output of 0 if the relational condition is not true, said relational condition being selected from the group consisting of A>B and A<B; and

a multiplexor (MUX) having input ports D0, D1, and D2 and select inputs SEL1 and SEL2, said D0 configured to receive to receive A from the adder, said D1 configured to receive B from the adder; said D2 configured to receive to receive a Large State Metric Value (LSMV), said LSMV being positive and sufficiently large if said relational condition is A>B or said LSMV being negative and sufficiently large if said relational condition is A<B, said SEL1 configured to be set to 0 if said X→Z and Y→Z are both legal, said SEL1 configured to be set to 1 if said X→Z and Y→Z both illegal, said SEL2 configured to receive the comparator output from the comparator, if SEL1=0 then said MUX configured to select D0 if SEL2=0 or to select D1 if SEL2=1, if SEL1=1 then said MUX configured to select D2, said MUX generating a MUX output of what the MUX has selected, said ST_Z=said MUX output.

The present invention provides a method and apparatus that more accurately detects a played-back sequence of binary bits with little increase in hardware complexity and negligible change in computation speed.

### BRIEF DESCRIPTION OF THE DRAWINGS

FIG. 1 depicts a 16-state viterbi trellis, in accordance with embodiments of the present invention.

FIG. 2 depicts a butterfly connection in a viterbi trellis, in accordance with embodiments of the present invention.

FIG. 3 depicts a 16-state viterbi trellis of FIG. 1 and shows branches having three consecutive state transitions, in accordance with embodiments of the present invention.

FIG. 4 depicts targeted branches to be made illegal in relation to the branches in FIG. 3 having three consecutive state transitions, in accordance with embodiments of the present invention.

FIG. 5 depicts a hardware implementation of making the targeted branches of FIG. 4 illegal, in accordance with embodiments of the present invention.

FIGS. 6-9 is a table of 4, 3, 2, and 1 restrictions, respectively, for a 16-state trellis, in accordance with embodiments of the present invention.

FIG. 10 is a table of 4, 3, 2, and 1 restrictions for a 16-state trellis, such that implemented restrictions are segregated from forced transitions, in accordance with embodiments of the present invention.

FIG. 11 depicts a hardware implementation of making particular branches of FIG. 3 illegal, in accordance with embodiments of the present invention.

### DETAILED DESCRIPTION OF THE INVENTION

Sequential data streams of binary bits may be written to a medium such as, inter alia, a magnetic medium or an optical medium. A statistical method that may be used for detecting a played-back sequence of the binary bits is the method of maximum likelihood detection using a viterbi trellis. The viterbi trellis is utilized for performing the maximum likelihood calculations used in estimating the played-back sequence of binary bits. Noting that binary code words derived from the binary bit sequence are stored to a memory depth of N bits (N>2), which defines 2^{N} binary states. This method projects the 2^{N} binary states onto the trellis at each discrete time that a new binary bit is read or played back. A binary bit is assumed to have two possible values such as, inter alia, 0 and 1. For each of the 2^{N} binary states at time Tᵢ₊₁, the resulting trellis comprises 2 logical branches from the 2^{N} binary states at a closest previous time Tᵢ, which defines a total of 2^{N+1} logical branches between Tᵢ and Tᵢ₊₁. A “logical branch” is a logically possible branch between Tᵢ and Tᵢ₊₁ in light of the fact that the played-back binary bit at time Tᵢ₊₁ must have exactly one of two possible values (e.g., 0 or 1). Although there are 2^{2N} path segments between the 2^{N} states at Tᵢ and the 2^{N} states at Tᵢ₊₁, most of the 2^{2N} path segments are logically impossible and thus cannot be logical branches. Indeed, only 2^{N+1} of the 2^{2N} path segments are logical branches. Definitionally, the term “branch” means a logical branch. A branch to a state at time Tᵢ₊₁ is between a state at time Tᵢ and the state at time Tᵢ₊₁. A branch from a state at time Tᵢ is between the state at time Tᵢ and a state at time Tᵢ₊₁. A “state transition” or “transition” is a transition from a first binary state at Tᵢ to a second binary state at Tᵢ₊₁, and such a transition is represented in a viterbi trellis by a branch. The term “path” designates a sequential ordering of branches, wherein said path moves forward in time through the trellis.

At each time Tᵢ₊₁, the maximum likelihood detection determines for each of the 2^{N} states the most likely path through the trellis that terminates in each of the 2^{N} states, said determination being accomplished by eliminating 2^{N} of the 2^{N+1} branches between every pair of successive states at times Tᵢ and Tᵢ₊₁. Each of the surviving 2^{N} paths at time Tᵢ₊₁ comprises a finite number of branches such that each such branch has a “length” that is called a “branch metric,” and each surviving path has a cumulative length over its branches, said cumulative length being called a “state metric.” The “length” is not necessarily a geometric dimension or distance but rather is a measure of a relevant physical parameter such as a voltage differential. After the entire binary bit sequence has been read or played back, the state metric of each of the 2^{N} final surviving paths is compared with an “empirical metric” that is derived from the actual measured sequence of binary bits. The final surviving path whose state metric is closest to the empirical metric is considered to define the most likely sequence of played-back binary bits. Since each branch metric is subject to such statistical errors as, inter alia, intersymbol interference and Guassian white noise, there is a statistical uncertainty in the maximum likelihood detection result. The present invention reduces the statistical uncertainty in maximum likelihood calculations by making “illegal” those branches that are known a priori to be impossible or highly improbable. What is “highly improbable” is application dependent; for example, a branch having a probability of 10⁻⁶ or less may be highly improbable in some applications, while a branch having a probability of 10⁻²⁰ or less may be highly improbable in other applications. A branch is said to be made “illegal” if no final surviving path can include the illegal branch. A “legal” branch is a branch that is not illegal. An “illegal state transition” or an “illegal transition” is a transition between states along an illegal branch. A “legal state transition” or a “legal transition” is a transition between states along a legal branch.

Given a memory depth of N bits, the viterbi trellis displays 2^{N} binary states at each time Tᵢ. In addition, the trellis comprises 2^{N+1} branches between the 2^{N} binary states at successive times Tᵢ and Tᵢ₊₁. The maximum likelihood calculations compute a branch metric for each such branch. However, some branches may be forbidden or highly improbable for extrinsic reasons. The present invention exploits knowledge of such forbidden or highly improbable branches and imposes restrictions on targeted branches that are associated or linked with the forbidden or highly improbable branches. Such restrictions make the targeted branches illegal, which reduces a statistical errors associated with the maximum likelihood calculations.

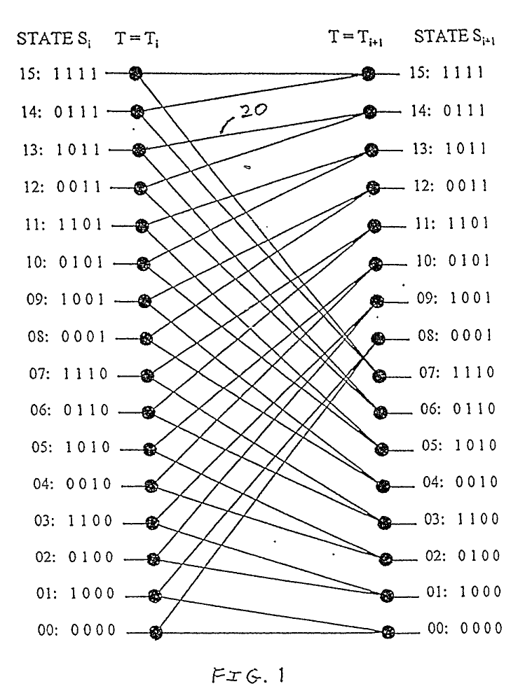

FIG. 1 illustrates a 16-state viterbi trellis corresponding to a memory depth of 4 binary bits, in accordance with embodiments of the present invention. The 16 binary states in FIG. 1 are expressed in binary form (i.e., 0 0 0 0, 1 0 0 0, . . . , 1 1 1 1) and in decimal form (i.e., 00, 01, . . . , 15). Generally, a memory depth of N bits (N>2) has an associated 2^{N} binary states and is characterized by storage in memory of the last N bits read. Thus, if a sequence of played-back bits are denoted as B₁, B₂, . . . , Bᵢ, Bᵢ₊₁, . . . , then after bit Bᵢ is read the last N bits read (i.e., Bᵢ₋ₙ₊₁, Bᵢ₋ₙ₊₂, . . . , Bᵢ₋₁, Bᵢ) are stored in memory. When the next bit Bᵢ₊₁ is read, then the corresponding next set of N bits (i.e., Bᵢ₋ₙ₊₂, . . . , Bᵢ, Bᵢ₊₁) are stored in memory. The N bits stored in memory at any given time collectively constitute one of the possible 2^{N} states. For the example in FIG. 1 in which N=4 for a 16-state viterbi trellis, if the bits B₃, B₄, B₅, B₆ are stored in memory just after the bit B₆ is read, then the bits B₃, B₄, B₅, B₆ collectively constitute one of the possible 16 binary states depending on the values (i.e., 0 or 1) of each of bits B₃, B₄, B₅, B₆. Similarly, if the bits B₄, B₅, B₆, B₇ are stored in memory just after bit B₇ is read, then the bits B₄, B₅, B₆, B₇ collectively constitute one of the possible 16 binary states.

FIG. 1 shows the 16 possible binary states at two successive times, namely at time Tᵢ and time Tᵢ₊₁. Denoting Bᵢ and Bᵢ₊₁ as the binary bits (i.e., 0 or 1) read at time Tᵢ and Tᵢ₊₁, respectively, the binary state Sᵢ (called “input state”) at time Tᵢ consists of the binary bits Bᵢ₋₃, Bᵢ₋₂, Bᵢ₋₁, Bᵢ, and the binary state Sᵢ₊₁ (called “output state”) at time Tᵢ₊₁ consists of the binary bits Bᵢ₋₂, Bᵢ₋₁, Bᵢ, Bᵢ₊₁. For some cases, the state Sᵢ may not be formed to a memory depth of N bits before N bits have been read or played back, and for such cases a minimum value of i for which Sᵢ exists is N (i.e., Sᵢ is defined if i≧N). For other cases, an initial state Sᵢ may be constrained to a predefined value (e.g., any of the 2^{N} values of 00, 01, . . . , 2^{N-1}), and for such cases Sᵢ is defined if i≧1.

Each line in FIG. 1 between Sᵢ and Sᵢ₊₁ denotes a transition from Sᵢ to Sᵢ₊₁, or equivalently a branch” between Sᵢ and S₊₁. For example, the line or branch 20 defines a transition from state 13 to state 14. The state Sᵢ₊₁ is related to the state Sᵢ by dropping the leftmost bit Bᵢ₋₃ of Sᵢ, and adding (rightmost) the next read bit Bᵢ₊₁. Since Bᵢ₊₁ has exactly 2 possible values, there are exactly 2 possible transitions from Sᵢ to Sᵢ₊₁. Thus, each of the 16 possible binary states (i.e., 00, 01, . . . , 15) of Sᵢ may be connected to Sᵢ₊₁ by either of 2 possible branches, as shown in FIG. 1. For example, the possible state 07 of Sᵢ at time Tᵢ may transition to only state 03 or state 11 of Sᵢ₊₁ at time Tᵢ₊₁, and each of said 2 transitions are denoted by branches in FIG. 1. Additionally, each of the 16 possible binary states (i.e., 00, 01, . . ., 15) of Sᵢ₊₁ at time Tᵢ₊₁ may be connected from Sᵢ by either of 2 successive branches, as shown in FIG. 1. For example, the possible state 12 of Sᵢ₊₁ at time Tᵢ₊₁ may be transitioned to from only successive states 08 and 09 of Sᵢ at time Tᵢ, and each of said 2 transitions are denoted by branches in FIG. 1. In FIG. 1, the trellis with the states and branches thereon exemplifies a “trellis structure.”

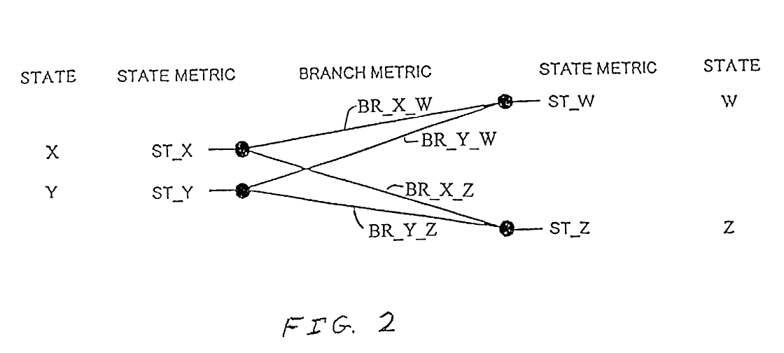

The preceding branching topology between input state Sᵢ and output state Sᵢ₊₁ exemplifies “butterfly connections.” FIG. 2 illustrates butterfly connections generally between input states X and Y (at time Tᵢ), and output states W and Z (at time Tᵢ₊₁). FIG. 2 also shows a branch metric BR_X_W between states X and W, a branch metric BR_Y_W between states Y and W, a branch metric BR_X_Z between states X and Z, and a branch metric BR_Y_Z between states Y and Z. Additionally, FIG. 2 shows state metrics ST_X, ST_Y, ST_W, and ST_Z at states X, Y, W, and Z, respectively. ST_W and ST_Z are calculated via:

ST_{—}W=minimum of: (ST_{—}X+BR_{—}X_{—}W) and (ST_{—}Y+BR_{—}Y_{—}W) (1)

ST_{—}Z=minimum of: (ST_{—}X+BR_{—}X_{—}Z) and (ST_{—}Y+BR_{—}Y_{—}Z) (2)

Since states X and Y are at time Tᵢ, and states W and Z are at time Tᵢ₊₁, Equations (1) and (2) provide an iterative prescription for calculating state metrics at any time, subject to an initial condition of the state metrics each being zero at an initial time corresponding to a reading of the first N bits (i.e., first 4 bits if N=4) of the binary bit sequence. Thus, from Equations (1) and (2), together with the initial conditions, a state metric is iteratively calculated at each time Tᵢ₊₁ as a summation of previous branch metrics. At the end of the binary bit play-back sequence when all of the played-back bits have been read, the 2^{N} calculated state metrics become the final state metrics associated with the 2^{N} final surviving paths required for the maximum likelihood determination of the most likely sequence of played back binary bits.

Note that Equations (1) and (2) could be replaced by Equations (3) and (4) respectively (discussed infra) in which “minimum of” is replaced by “maximum of.” For situations in which Equations (3) and (4) apply, any discussion infra that refers to Equations (1) and (2) applies alternatively to Equations (3) and (4) with the understanding any mention of a “minimum” in relation to Equations (1)-(2) translates to a “maximum” in relation to Equations (3)-(4).

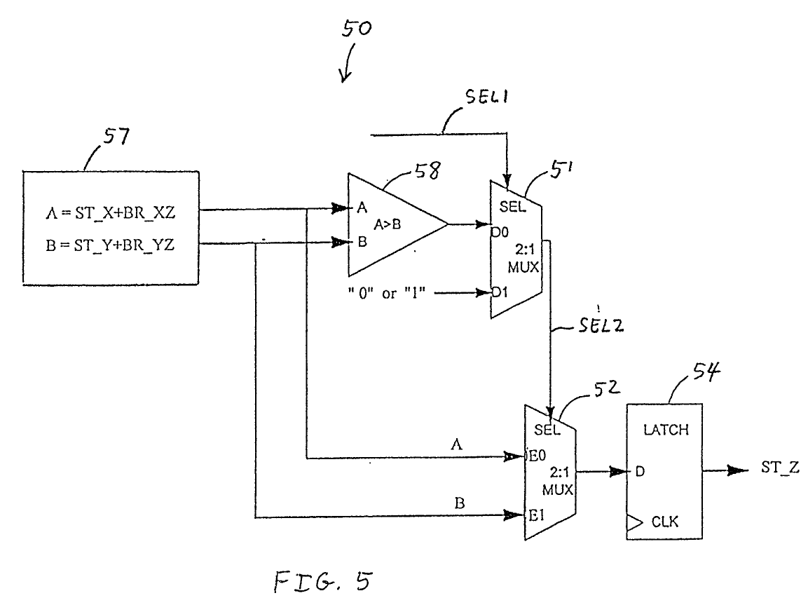

Equations (1) and (2) describe an Add-Compare-Select (ACS) operation for determining a state metric for a given output state, which is implementable in hardware as will be described infra in conjunction with FIGS. 5 and 11. In Equation (1), for example, the state metric ST_W for the output state W is computed by ACS as follows. “Add” comprises adding the branch metric BR_X_W to the state metric ST_X to form (ST_W)_{X}, and adding the branch metric BR_Y_W to the state metric ST_Y to form (ST_W)_{Y}. “Compare” comprises comparing (ST_W)_{X} with (ST_W)_{Y}. “Select” comprises selecting the minimum of (ST_W)_{X} and (ST_W)_{Y} based on the result of the “Compare”. In a similar fashion, the state metric ST_Z is computed by ACS in accordance with Equation (2).

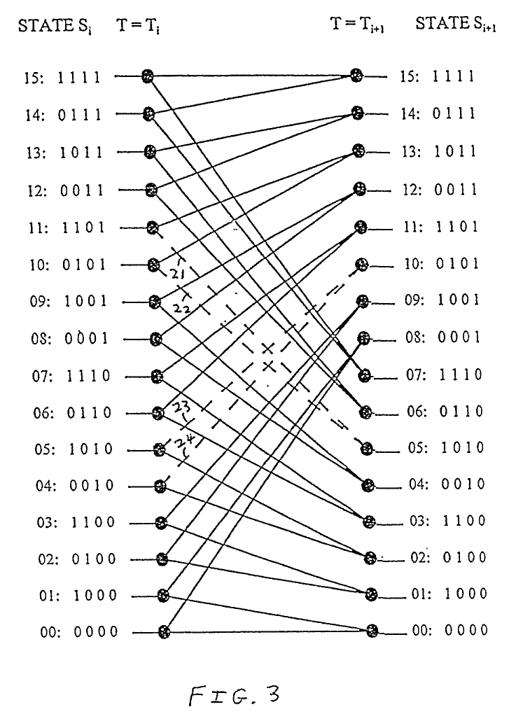

Using the iterative procedure of Equations (1) and (2) with each of the 2^{N} output states at each time Tᵢ₊₁ requires 2^{N-1} applications of Equation (1) and 2^{N-1} applications of Equation (2) at each time Tᵢ₊₁ in terms of the 2^{N+1} branches between Tᵢ and Tᵢ₊₁. Each branch metric contributes to a statistical uncertainty of the result of the maximum likelihood determination. The present invention is directed to improving the accuracy of the maximum likelihood determination, through hardware implementation that makes certain branches and corresponding state transitions illegal. For example, if in FIG. 2 the transition between state X and state Z were made illegal (because such transition were known a priori to be impossible or highly improbable), then making such transition between state X and state Z illegal eliminates the statistical error associated with such transition. FIGS. 3-11 illustrate how the present invention makes certain state transitions illegal, using methodology and hardware implementation that does not materially increase hardware complexity or decrease computation speed.

FIG. 3 depicts the 16-state viterbi trellis of FIG. 1 and shows branches having three consecutive state transitions, in accordance with embodiments of the present invention. A “consecutive transition” between states Sᵢ and Sᵢ₊₁ with associated last played-back binary bits Bᵢ and Bᵢ₊₁, respectively, is said to occur if Bᵢ₊₁ ≠Bᵢ (e.g., if Bᵢ and Bᵢ₊₁ are 0 and 1 respectively, or 1 and 0 respectively). The branches from time Tᵢ to time Tᵢ₊₁ having three consecutive state transitions consist of branch 21 (denoting a transition from state 11 to state 05), branch 22 (denoting a transition from state 10 to state 05), branch 23 (denoting a transition from state 05 to state 10), and branch 24 (denoting a transition from state 04 to state 10). The number of consecutive state transitions is the binary word SᵢBᵢ₊₁. For example, the pertinent binary word for the transition from state 11 to state 05 is 11010 (i.e., “1101” and “0” in sequence), since Sᵢ=1101 and Bᵢ₊₁=0. An inspection of 11010 reveals three consecutive state transitions (i.e., 1 to 0, 0 to 1, and 1 to 0, in sequence from left to right). Generally for a memory depth of N binary bits, the pertinent binary word for determining whether M consecutive state transitions have occurred (0≦M≦N) is SᵢBᵢ₊₁ which has N+1 binary bits.

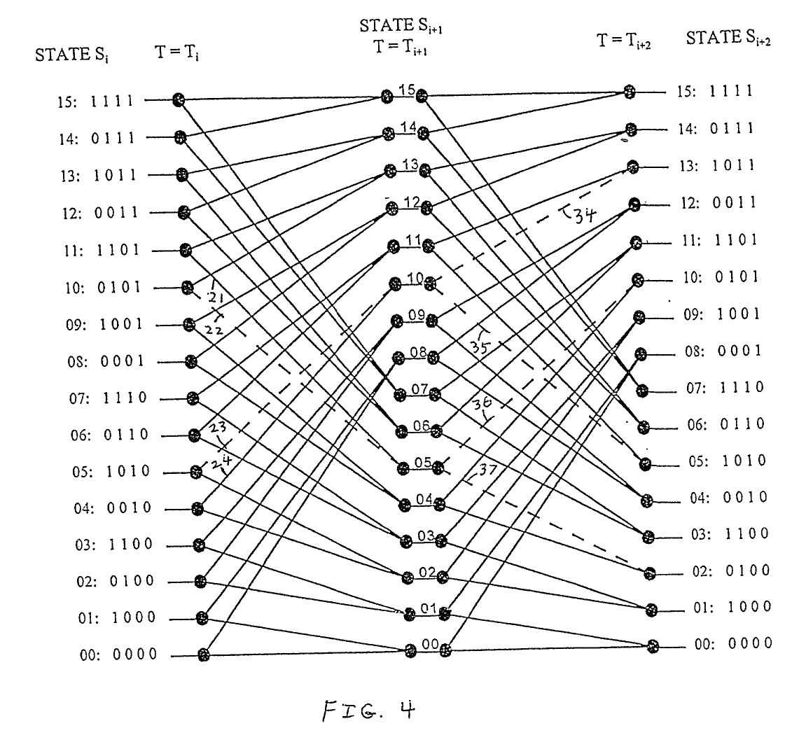

With magnetic recording of binary data, multiple consecutive transitions may introduce errors and may therefore be undesirable. If such multiple consecutive transitions are impossible or highly improbable, then making such multiple consecutive transitions or branches illegal would prevent all paths which include an illegal branch from becoming a final surviving path. Accordingly, the illegal branches would reduce statistical errors or uncertainties as to which final surviving path is the most likely path and thus improve the reliability of the maximum likelihood detection calculations. As an example, FIGS. 3-5 and 11 illustrate how branches having three consecutive transitions (and associated branches) can be made illegal, and illegal branches are denoted by dashed lines in FIGS. 3 and 4). Making three consecutive transitions illegal in FIG. 3 may be accomplished if the branches 21-24 in FIG. 3 could each be made illegal. It is noted in FIG. 3 that branches 21 and 22 each terminate in the same output state 05, and that branches 23 and 24 each terminate in the same output state 10. However, the present invention discloses an embodiment in which the two branches terminating in each output state constitute either two legal branches, or one legal branch and one illegal branch, as shown in FIG. 4 in accordance with a hardware configuration of FIG. 5. Thus, the aforementioned embodiment implements FIG. 4 rather than FIG. 3.

FIG. 4 shows three successive times Tᵢ, Tᵢ₊₁, Tᵢ₊₂ at which reading binary bits Bᵢ, Bᵢ₊₁, Bᵢ₊₂, respectively, have been read and at which binary states Sᵢ, Sᵢ₊₁, Sᵢ₊₂, respectively, have been formed. The times Tᵢ and Tᵢ₊₁ are the same times in FIGS. 3 and 4, and FIG. 4 shows the next successive time Tᵢ₊₂ which follows Tᵢ₊₁. FIG. 4 shows targeted branches (or state transitions) 22, 23, 34, 35, 36, and 37 to be made illegal in relation to the branches 21-24 in FIG. 3, in accordance with embodiments of the present invention. FIG. 4 shows as illegal the same branches 22 and 23 that were denoted as illegal in FIG. 3. Nonetheless, FIG. 4 does not show as illegal branches 21 and 24 which had been denoted as illegal in FIG. 3. The branches 21 and 24 are each subject to the “forced legal restriction” of being forced to be legal when they are intended to be illegal. Thus, the branches 21 and 24 are examples of “forced legal” branches. FIG. 4 shows as illegal branches 36 and 37 instead of branch 21. Additionally, FIG. 4 shows as illegal branches 34 and 35 instead of branch 24. A “forced transition” is a transition along a forced legal branch. A “paralegal” branch designates a branch that is either a legal branch or a forced legal branch. The rationale behind the forced legal branches (or forced transitions) of FIG. 4 is as follows.

In FIG. 3, branches 21 and 22 both lead to state 05 at time Tᵢ₊₁. Thus, state 05 at time Tᵢ₊₁ should not occur since no legal branch leads to state 05 at time Tᵢ₊₁. While FIG. 4 shows branch 21 as forced legal so that state 05 could occur at time Tᵢ₊₁, FIG. 4 also shows as illegal branches 36 and 37 which encompass all possible transitions from state 05 at time Tᵢ₊₁. Although a transition (i.e., from state 11 to state 05) along forced legal branch 21 can reach state 05 at time Tᵢ₊₁, no transition can occur from state 05 at time Tᵢ₊₁. Thus, the task of making branch 21 illegal at time Tᵢ has been replaced by the task of making branch 21 forced legal and making branches 36 and 37 illegal at time Tᵢ₊₁. Similarly, the task of making branch 24 illegal at time Tᵢ has been replaced by the task of making branch 24 forced legal and making branches 34 and 35 illegal at time Tᵢ₊₁. With the targeted branches 22, 23, 34, 35, 36, and 37 in FIG. 4 to be made illegal, all output states in the time varying trellis of FIG. 4 (i.e., at times Tᵢ₊₁ and Tᵢ₊₂) are at a termination of either two legal branches or at a termination of one legal branch and one illegal branch, which satisfies the criteria for an “Illegal Branch Exclusion” (IBE) method, to be described infra.

FIG. 5 depicts an apparatus 50 for computing state metrics at times Tᵢ₊₁ and Tᵢ₊₂ in consideration of making the targeted branches 22, 23, 34, 35, 36, and 37 illegal (see FIG. 4). The apparatus 50 in FIG. 5 computes a state metric ST_Z of an output state Z from two input states X and Y. The apparatus 50 computes ST_Z by selecting the branch from X to Z or the branch from Y to Z. The branch selected (X→Z or Y→Z) becomes a component of the surviving path terminating in state Z.

The apparatus 50 in FIG. 5 implements the “Illegal Branch Exclusion” (IBE) method, which is applicable if X→Z and Y→Z are both legal, or that one of X→Z and Y→Z is illegal and the other of X→Z and Y→Z is paralegal. If X→Z and Y→Z are both legal, then ST_Z is calculated in accordance with Equation (2); and if one of X→Z and Y→Z is illegal and the other of X→Z and Y→Z is paralegal, then ST_Z is calculated based on excluding the one of X→Z and Y→Z that is illegal and thus selecting the other of X→Z and Y→Z that is paralegal.

The apparatus 50 comprises an adder 57, a comparator 58, a 2:1 multiplexer (MUX) 51, a 2:1 MUX 52, and a latch 54. The MUX 51 has input ports D0 and D1, and select input SEL1. The MUX 51 effectuates a selection of either input at D0 or input at D1 based on whether SEL1 has a value 0 or 1, respectively. The MUX 52 has input ports E0 and E1, and select input SEL2. The MUX 52 selects input at E0 or input at E1 based on a whether SEL2 has a value of 0 or 1, respectively. The latch 54 has input port D and a clock CLK.

The adder 57 computes A=ST_X+BR_X_Z and B=ST_Y+BR_Y_Z. Defining a relational condition as A>B, the comparator 58 compares A and B, and computes comparator 58 output as “1” if the relational condition is true, or as “0” if the relational condition is false. For the MUX 51, the port D0 accepts the comparator 58 output as input and the port D1 accepts either “0” or “1” as input. For the MUX 52, the port E0 accepts A as input and the port E1 accepts B as input.

If SEL1=0 then the MUX 51 selects D0, and if SEL1=1 then the MUX 51 selects D1. SEL2 has the value that the MUX 51 selects. If SEL2=0 then the MUX 52 selects E0=A, and if SEL2=1 then the MUX 52 selects E1=B. The input port D of the latch 54 receives the output ST_Z from the MUX 52. ST_Z is released as output from the latch 54 after being held in the To latch 54 for an appropriate period of time, as shown.

If both X_Z and Y_Z branches are legal, then SEL1 is set to 0, and the preceding discussion shows that: if SEL2=0 then MUX 52 selects E0=A or if SEL2=1 then MUX 52 selects E1=B. Thus if both X→Z and Y→Z branches are legal, then ST_Z=the minimum of A and B in accordance with Equation (2). Alternatively if Equation (4) is used instead of Equation (2) and if both X→Z and Y→Z branches are legal, then ST_Z=the maximum of A and B in accordance with Equation (4).

If one (but not both) of X→Z and Y→Z branches are illegal, then SEL2 is set to D1. If Y→Z is illegal, then D1 is set to 0 and thus ST_Z=A=ST_X+BR_X_Z in selection of the legal branch X→Z and exclusion of the illegal branch Y→Z. If X→Z is illegal, then D1 is set to 1 and thus ST_Z=B=ST_Y+BR_Y_Z in selection of the legal branch Y→Z and exclusion of the illegal branch X→Z.

The apparatus 50 of FIG. 5 may be applied to the branches of FIG. 4 as follows. If both branches leading to a given output state are legal (e.g., branches 00→08 and 01→08 at time Ti) then set SEL1=0, resulting in choosing the output state metric (i.e., ST_Z) in accordance with Equation (2). If one of the two branches leading to a given output state is illegal and the other branch is paralegal, then set SEL1=1, and set D1=0 if Y→Z is illegal or set D1=1 if X→Z is illegal, as described supra. For example, with reference to FIG. 4, consider output state Z=05 at time Tᵢ₊₁, and input states X=11 and Y=10 at time Tᵢ. SEL1 is set to 1, and since Y→Z (i.e., 10→05) is illegal, D1 is set to 0 and ST_{—}05=ST_{—}11+BR_{—}11_{—}05. As another example, also with reference to FIG. 4, consider output state Z=02 at time Tᵢ₊₂, and input states X=05 and Y=04 at to time Tᵢ₊₁. SEL1 is set to 1, and since X→Z (i.e., 05→02) is illegal, D1 is set to 1 and ST_{—}02=ST_{—}04+BR_{—}04_{—}02. Thus, the apparatus 50 of FIG. 5 could be used to compute a state metric for each output state at T=Tᵢ₊₁ and T=Tᵢ₊₂ in FIG. 4 by making appropriate choices for SEL1 and D1 for each output state.

Since a legal branch and a forced legal branch are indistinguishable to the apparatus 50 of FIG. 5, the apparatus 50 applies in a same fashion to both legal and forced legal branches. Thus, the apparatus 50 is generally applicable to a paralegal branch in combination with an illegal branch, as described supra.

If there were no illegal branches, then SEL1 and MUX1 would be unnecessary and the apparatus 50 of FIG. 5 would always calculate ST_Z in accordance with Equation (2). Thus having SEL1 and MUX1 as part of the apparatus 50 is necessary to enforce illegal branches. Fortunately, usage of SEL1 and MUX1 has a negligible impact on computing speed and adds negligible complexity to the apparatus 50.

The apparatus 50 for applying the IBE method is identified herein as a TVT_M2M2 apparatus. “TVT” stands for Time Varying Trellis control, as embodied in SEL1 in FIG. 5. “M2M2” stands for a first 2:1 MUX and a second 2:1 MUX, as embodied in the MUX 51 and the MUX 52, respectively, in FIG. 5.

With the viterbi trellis in FIG. 4, the transitions or branches which are made illegal are a cyclical function of time. Thus, the viterbi trellis in FIG. 4 is a time varying trellis. An example that applies the viterbi trellis in FIG. 4 to three time steps per cycle is illustrated as follows in Table 1, wherein two cycles are depicted as a cycle counter steps through time and the cycle counter is reset after each group of three time steps.

TABLE 1
Illegal Branches With Three Time Steps Per Cycle, Based on FIG. 4

| | | Initial | | |
|---|---|---|---|---|
| Cycle | Counter | Time | SEL1 | Branches To Make Illegal |
| 1 | 1 | Tᵢ | 1 | 05 → 10; 10 → 05 |
| 1 | 2 | Tᵢ₊₁ | 1 | 10 → 13; 10 → 05; 05 → 10; 05 → 02 |
| 1 | 3 | Tᵢ₊₂ | 0 | None (all transitions are legal) |
| 2 | 1 | Tᵢ₊₃ | 1 | 05 → 10; 10 → 05 |
| 2 | 2 | Tᵢ₊₄ | 1 | 10 → 13; 10 → 05; 05 → 10; 05 → 02 |
| 2 | 3 | Tᵢ₊₅ | 0 | None (all transitions are legal) |
| . | . | . | . | . |
| . | . | . | . | . |
| . | . | . | . | . |

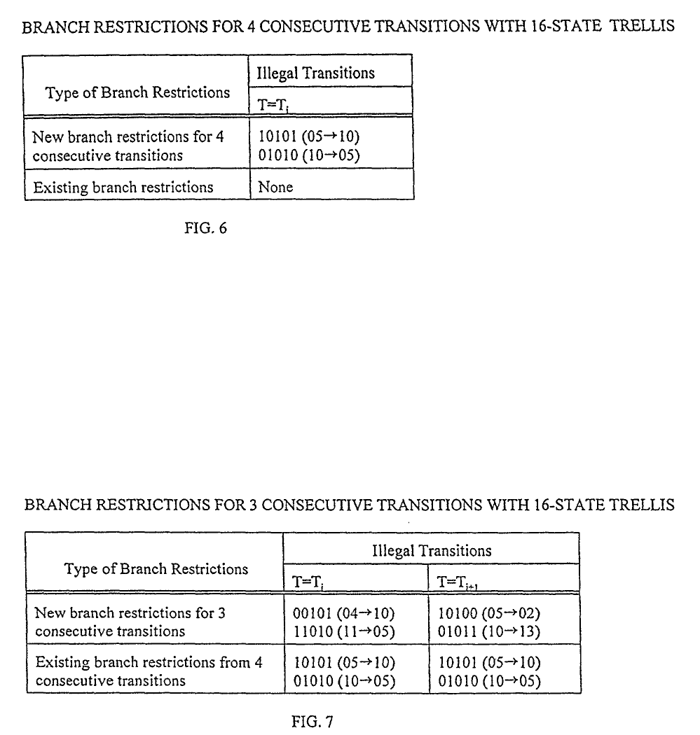

FIGS. 6-9 depicts tables of illegal transitions (or associated illegal branches) for 4, 3, 2, and 1 consecutive transitions, respectively, for a 16-state trellis having an associated memory depth of 4. FIG. 4 shows 2 illegal transitions pertaining to 4 consecutive transitions, namely the 05→10 and 10→05 transitions at T=Tᵢ, which correspond to branches 23 and 22 of FIG. 4 at T=Tᵢ, respectively. The illegal 05→10 and 10→05 transitions at T=Tᵢ may be implemented by the apparatus 50 of FIG. 5 by setting SEL1=1 as discussed supra.

FIG. 7 shows illegal transitions pertaining to 3 consecutive transitions, namely 2 “new” branch restrictions (i.e., illegal state transitions) and 2 “existing” restrictions. A “branch restriction” denotes an illegal branch between two states or a corresponding illegal transition between the two states. The “existing” branch restrictions were previously denoted for 4 consecutive transitions in FIG. 6. The “new” branch restrictions are specific to 3 consecutive transitions and are not branch restrictions for 4 consecutive transitions. The illegal transitions shown in FIG. 7 are shown in FIG. 4 and were specifically discussed supra in conjunction with FIG. 4. The illegal transitions shown in FIG. 7 may be implemented by the apparatus 50 of FIG. 5 by setting SEL1=1 as discussed supra. Note that some of the illegal transitions in FIG. 7 (i.e., the 04→10 and 11→05 transitions at T=Tᵢ) are “forced transitions”; i.e., forced to be legal for use with the apparatus 50 of FIG. 5, as discussed supra.

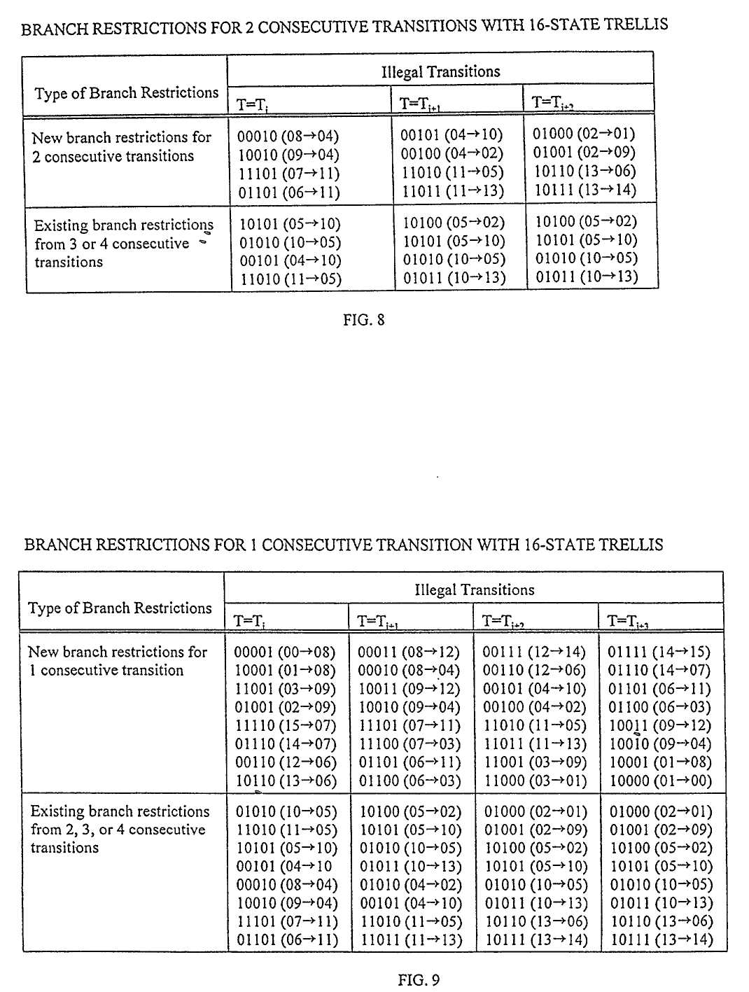

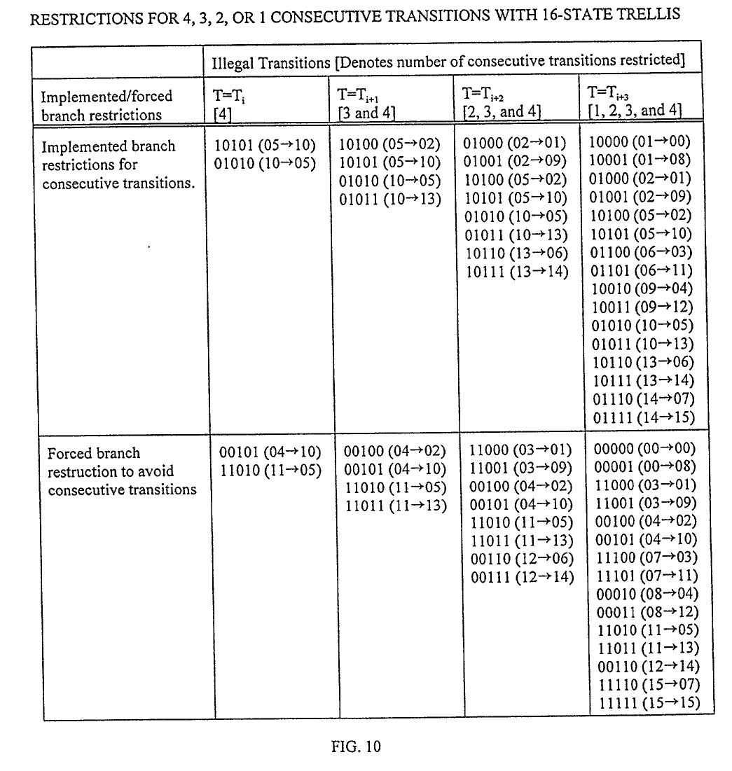

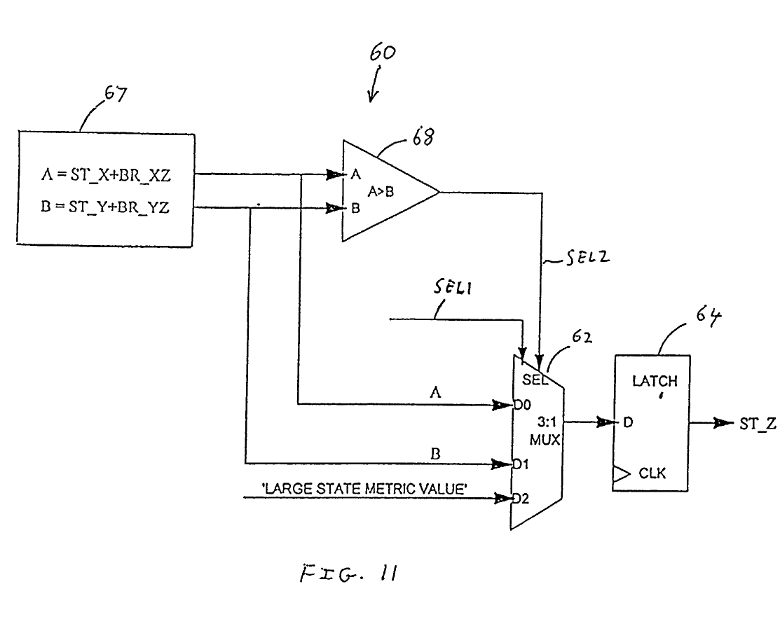

FIG. 8 shows illegal transitions pertaining to 2 consecutive transitions, including new and existing branch restrictions. The existing branch restrictions were previously denoted for 3 or 4 consecutive transitions in FIG. 7. The new branch restrictions are specific to 2 consecutive transitions and are not branch restrictions for 3 or 4 consecutive transitions. As with the forced transitions for 3 consecutive transitions discussed supra in conjunction with FIG. 4, some of the illegal transitions in FIG. 8 are forced to be legal so that the apparatus 50 of FIG. 5 could be utilized. FIG. 10, to be discussed infra, shows which illegal transitions in FIG. 8 are forced transitions. The illegal transitions in FIG. 8 may implemented by the apparatus 50 of FIG. 5 by setting SEL1=1.

FIG. 9 shows illegal transitions pertaining to 1 consecutive transition, including new and existing branch restrictions. The existing branch restrictions were previously denoted for 2, 3, or 4 consecutive transitions in FIG. 8. The new branch restrictions are specific to 1 consecutive transition and are not branch restrictions for 2, 3, or 4 consecutive transitions. As with the forced transitions for 3 consecutive transitions discussed supra in conjunction with FIG. 4, some of the illegal transitions in FIG. 9 are forced to be legal so that the apparatus 50 of FIG. 5 could be utilized. FIG. 10, to be discussed infra, shows which illegal transitions in FIG. 9 are forced transitions. The illegal transitions in FIG. 9 may implemented by the apparatus 50 of FIG. 5 by setting SEL1=1.

FIG. 10 is a table of 4, 3, 2, and 1 restrictions for a 16-state trellis, such that implemented restrictions are segregated from forced transitions, in accordance with embodiments of the present invention. FIG. 10 combines the restrictions in FIGS. 6-9 to depict a set of rules that restricts consecutive transitions of varying lengths for the 16-state trellis, in order to facilitate utilization of the apparatus 50 of FIG. 5. Using the 16-state trellis, FIG. 10 shows that 4 consecutive transitions can be restricted only at T=Tᵢ, but 3 consecutive transitions can be restricted at T=T, and/or T=Tᵢ₊₁, since restricting 3 transitions also must restrict 4 transitions. Similarly, 2 consecutive transitions can be restricted at T=Tᵢ, T=Tᵢ₊₁, and/or T=Tᵢ₊₂, and 1 consecutive transitions can be restricted at T=Tᵢ, T=Tᵢ₊₁, T=Tᵢ₊₂, and/or Tᵢ₊₃. The structure of Table 10 can be extended to form a common set of restrictions that project out in time (i.e., to times Tᵢ₊₄, Tᵢ₊₅, Tᵢ₊₆, . . . , etc. Therefore, by using forced restrictions in conjunction with targeted restrictions in future time, wherein the targeted restrictions correlate with the forced restrictions as discussed supra for the example of FIG. 4, FIG. 10 may be utilized for implementing the apparatus 50 of FIG. 5. This solution, of applying the apparatus 50 of FIG. 5 to forced transitions and associated targeted transitions, enables time varying trellis control methodology to maximum likelihood detection calculations, with negligible computing speed impact and very little hardware increase.

While the IBE method and apparatus 50 of FIG. 5 were utilized herein to make certain branches or state transitions illegal in maximum likelihood detection calculations, the scope of the present invention includes making branches or state transitions illegal generally. Another method that could be used for making branches or state transitions in a trellis illegal is the “LARGE STATE METRIC VALUE” (LSMV) method. The LSMV method may be illustrated for making 3 consecutive transitions illegal in relation to the trellis shown in FIG. 3, as implemented by using an apparatus 60 in FIG. 11. In FIG. 3, the branches 21-24 could be made effectively illegal (i.e., their effect on maximum likelihood detection calculations could be made negligibly small) if the state metrics at states 05 and 10 at T=Tᵢ₊₁ could be assigned a large value (in magnitude) called a LSMV. LSMV should be “sufficiently large.” LSMV is “sufficiently large” if LSMV is large enough in magnitude to cause a subsequent calculation of the 2^{N} state metrics at the next sequential time Tᵢ₊₂ to exclude all branches from the states (e.g., 05 and 10 states) at T=Tᵢ₊₁ that logically connect to states at time Tᵢ₊₂.

FIG. 11 depicts the apparatus 60 for making the branches 21-24 effectively illegal. The apparatus 60 in FIG. 11 computes a state metric ST_Z of an output state Z from two input states X and Y, wherein Equation (2) may be utilized. The apparatus 60 computes ST_Z by selecting the branch from X to Z or the branch from Y to Z. The branch selected (X→Z or Y→Z) becomes a component of the surviving path terminating in state Z. However, if the apparatus 60 assigns a LSMV to SM_Z, then selection of the branch X→Z or Y→Z is irrelevant to determining the surviving paths at Tᵢ₊₂, since the subsequent calculation of the 2^{N} state metrics at the next sequential time Tᵢ₊₂ will exclude all branches from the state Z at T=Tᵢ₊₁ that logically connect to states at time Tᵢ₊₂. Thus, the LSMV method could be used for cases in which the paths X→Z and Y→Z are both intended to be illegal such that their illegality is not directly imposed but indirectly simulated by assigning the LSMV to ST_Z.

The LSMV method assumes that X→Z and Y→Z are both legal or both illegal, such that: if X→Z and Y→Z are both legal, then ST_Z is calculated in accordance with Equation (2); and if X→Z and Y→Z are both illegal, then ST_Z is assigned to the LSMV.

The apparatus 60 comprises an adder 67, a comparator 68, a 3:1 MUX 62, and a latch 64. The MUX 62 has input ports D0, D1, and D2, and select inputs SEL1 and SEL2. The MUX 62 selects input at D0, input at D1, or input at D2 based on values of SEL1 and SEL2. The latch 64 has input port D and a clock CLK. The adder 67, comparator 68, and the MUX 62 may collectively constitute an ACS, as will be described infra.

The adder 67 computes A=ST_X+BR_X_Z and B=ST_Y+BR_Y_Z. Defining a relational condition as A>B, the comparator 68 compares A and B, and computes comparator 68 output as “1” if the relational condition is true, or as “0” if the relational condition is false. SEL2 receives the comparator 68 output. SEL1 is set to “0” or “1”. For the MUX 62, the port D0 accepts A as input, the port D1 accepts B as input, and the port D2 accepts the “LARGE STATE METRIC VALUE” (LSMV) as input.

If SEL1=0, then the MUX 62 selects D0 (i.e., A) if SEL2=0, or the MUX 62 selects D1 (i.e., B) if SEL2=1. If SEL1=1 then the MUX 62 selects D2 (i.e., the LSMV). The input port D of the latch 64 receives the output ST_Z from the MUX 62. ST_Z is released as output from the latch 64 after being held in the latch 64 for an appropriate period of time, as shown.

If both X→Z and Y→Z branches are legal, then SEL1 is set to 0, and the preceding discussion shows that if the relational condition is true, then SEL2=1 and MUX 62 selects D1=B; or if the relational condition is false, then SEL2=0 and MUX 62 selects D0=A. In summary, ST_Z=the minimum of A and B, in accordance with Equation (2). Alternatively, if the relational condition is A<B, then ST_Z=the maximum of A and B, in accordance with Equation (4) which is an alternative to Equation (2) that will be discussed infra.

If both X→Z and Y→Z branches are illegal, then SEL1 is set to 1, and the preceding discussion shows that the MUX 62 will select the LSMV regardless of the relative magnitudes of A and B, so that ST_Z=LSMV regardless of the relative magnitudes of A and B.

The apparatus 60 of FIG. 11 may be applied to the branches of FIG. 3 as follows. If both branches leading to a given output state are legal (e.g., branches 00→08 and 01→08 from time Tᵢ to time Tᵢ₊₁) then set SEL1=0, resulting in choosing the output state metric (i.e., ST_Z) in accordance with Equation (2). If both of the two branches leading to a given output state are illegal, then set SEL1=1 which results in ST_Z=LSMV. For example, with reference to FIG. 3, consider Z=05 at time Tᵢ₊₁, and X=11 and Y=10 at time Tᵢ. SEL1 is set to 1, and ST_{—}05=LSMV regardless of the relative magnitudes of ST_{—}11+BR11_{—}05 and ST_{—}10+BR10_{—}05. As another example, also with reference to FIG. 3, consider Z=10 at time Tᵢ₊₁, and X=05 and Y=04 at time Tᵢ. SEL1 is set to 1, and ST_{—}10=LSMV regardless of the relative magnitudes of ST_{—}05+BR05_{—}10 and ST_{—}04+BR04_{—}10. LSMV should be large enough that no branch from the states 05 and 10 at T=Tᵢ₊₁ to logically possible states at the next sequential time Tᵢ₊₂ would be selected when the state metrics at Tᵢ₊₂ are calculated, which is equivalent to making the branches 34-37 in FIG. 4 illegal. Thus, the apparatus 60 of FIG. 11 could be used to compute a state metric for each output state at T=Tᵢ₊₁ in FIG. 3 by making an appropriate choice for SEL1 for each output state.

The LSMV method assumes that X→Z and Y→Z are both legal or both illegal, such that: if X→Z and Y→Z are both legal, then ST_Z is calculated in accordance with Equation (2); and if X→Z and Y→Z are both illegal, then ST_Z is assigned the LSMV.

The apparatus 60 for implementing the LSMV method is identified herein as a TVT_M3 apparatus. “TVT” stands for Time Varying Trellis control, as embodied in SEL1 in FIG. 11 . “M3” stands for a 3:1 MUX, as embodied in the MUX 62 in FIG. 11.

While the restrictions (i.e., illegal branches) discussed herein relate to illegal consecutive transitions, the scope of the present invention includes branches or transitions made illegal for any purpose or reason.

While the viterbi trellis discussed herein relates to a 16-state trellis corresponding to a memory depth of 4, the scope of the present invention generally includes a 2N-state trellis corresponding to a memory depth of N, wherein N≧2.

While the viterbi trellis discussed herein relates to a time varying trellis, the scope of the present invention also includes a steady-state trellis. For example, the apparatus 50 of FIG. 5 could be make illegal the 4 consecutive transition branches shown in FIG. 6, even if this illegality is time invariant.

While Equations (1) and (2) each compute a minimum of two potential state metrics, in some applications the computation of a minimum in Equations (1) and (2) should be replaced by computation of a maximum. For such applications, Equations (1) and (2) should be replaced by Equations (3) and (4); i.e.,

ST_{—}W=maximum of: (ST_{—}X+BR_{—}X_{—}W) and (ST_{—}Y+BR_{—}Y_{—}W) (3)

ST_{—}Z=maximum of: (ST_{—}X+BR_{—}X_{—}Z) and (ST_{—}Y+BR_{—}Y_{—}Z) (4)

To illustrate, if Equations (1)-(2) should be used if the branch metrics are expressed as voltages, then Equations (3)-(4) should be used if the branch metrics are expressed as inverse voltages. Definitionally, Equations (1)-(4) shall each be identified as a “State Update Equation,” Equations (1)-(2) shall each be particularly identified as a “Minimizing State Update Equation,” and Equations (3)-(4) shall each be particularly identified as a “Maximizing State Update Equation.” The IBE method, the TVT_M2M2 apparatus, the LSMV method, and the TVT_M3 apparatus are each applicable to the use of Equations (1)-(2) or Equations (3)-(4) as alternatives. If Equations (3)-(4) are used instead of Equations (1)-(2), then the appropriate relational condition is A<B instead of A>B for the IBE method, the TVT_M2M2 apparatus, the LSMV method, and the TVT_M3 apparatus. In addition, if Equations (3)-(4) are used instead if Equations (1)-(2) in conjunction with the LSMV method or the TVT_M3 apparatus, then LSMV should be set to a large negative number that is “sufficiently large” as defined supra; i.e. in relation to FIG. 3, LSMV should be large enough in magnitude to cause a subsequent calculation of the 2^{N} state metrics at the next sequential time Tᵢ₊₂ to exclude all branches from the states at T=Tᵢ₊₁ that logically connect to states at time Tᵢ₊₂.

While embodiments of the present invention have been described herein for purposes of illustration, many modifications and changes will become apparent to those skilled in the art. Accordingly, the appended claims are intended to encompass all such modifications and changes as fall within the true spirit and scope of this invention.

We claim:

1. A method for maximum likelihood detection of a sequential stream of binary bits, comprising:
providing a trellis onto which 2^{N} binary states are projected at each discrete time of a sequence of times, said N≧2;
identifying, for each of the 2^{N} binary states at time Tᵢ₊₁, 2 branches to each of the 2^{N} binary states at time Tᵢ₊₁ from a closest previous time Ti for a total of 2^{N+1} such branches between Tᵢ and Tᵢ₊₁, said i≧N or i≧1;
providing a state metric for each of the 2^{N} binary states at Tᵢ and a branch metric for each of the 2^{N+1} branches between Tᵢ and Tᵢ₊₁;
designating a first illegal branch of said 2 branches to a state S1 at time Tᵢ₊₁;
selecting another branch of said 2 branches to the state S1 from the group consisting of a second illegal branch and a paralegal branch; and
computing a state metric at each of the 2^{N} binary states at time Tᵢ₊₁, said state metrics at Tᵢ₊₁ being functionally dependent upon: said state metrics at Tᵢ, said branch metrics between Tᵢ and Tᵢ₊₁, and said 2 branches to state S1.

2. The method of claim 1, wherein the another branch is the paralegal branch.

3. The method of claim 2, wherein computing the state metrics at Tᵢ₊₁ includes computing the state metrics at Tᵢ₊₁ in accordance with an IBE method.

4. The method of claim 3, wherein computing the state metrics at Tᵢ₊₁ in accordance with the IBE method includes computing by use of a TVT_M2M2 apparatus.

5. The method of claim 2, wherein the paralegal branch is a legal branch.

6. The method of claim 2, wherein the paralegal branch is a forced legal branch.

7. The method of claim 6, further comprising:
identifying, for each of the 2^{N} binary states at time Tᵢ₊₂, 2 branches from time Tᵢ₊₁ to each of the 2^{N} binary states at time Tᵢ₊₂ for a total of 2^{N+1} such branches between Tᵢ₊₁ and Tᵢ₊₂;
providing a branch metric for each of the 2^{N+1} branches between Tᵢ₊₁ and Tᵢ₊₂;
designating an illegal branch of said 2 branches to a state S2A at time Tᵢ₊₂ from the state S1;
designating a paralegal branch of said 2 branches to the state S2A;
designating an illegal branch of said 2 branches to a state S2B at time Tᵢ₊₂ from the state S1;
designating a paralegal branch of said 2 branches to the state S2B; and
computing a state metric at each of the 2^{N} binary states at time Tᵢ₊₂, said state metrics at Tᵢ₊₂ being functionally dependent upon said state metrics at Tᵢ₊₁, said branch metrics between Tᵢ₊₁ and Tᵢ₊₂, said 2 branches to the state S2A, and said 2 branches to the state S2B.

8. The method of claim 7, wherein computing the state metrics at Tᵢ₊₁ and Tᵢ₊₂ includes computing the state metrics at Tᵢ₊₁ and Tᵢ₊₂ in accordance with an IBE method.

9. The method of claim 8, wherein computing the state metrics at Tᵢ₊₁ and Tᵢ₊₂ in accordance with the IBE method includes computing by use of a TVT_M2M2 apparatus.

10. The method of claim 1, wherein the another branch is the second illegal branch.

11. The method of claim 10, wherein computing the state metrics at Tᵢ₊₁ includes computing the state metrics at Tᵢ₊₁ in accordance with a LSMV method.

12. The method of claim 11, wherein computing the state metrics at Tᵢ₊₁ in accordance with the LSMV method includes computing by use of a TVT_M3 apparatus.

13. The method of claim 1, wherein the state S1 includes M consecutive transitions, and wherein M is selected from the group consisting of 1, 2, . . . , and N.

14. The method of claim 1, wherein N=4.

15. A maximum likelihood detection trellis structure, comprising:
a trellis onto which 2^{N} binary states have been mapped at each discrete time of a sequence of times, said N≧2;
2 branches to each of the 2^{N} binary states at time Tᵢ₊₁ from a closest previous time Tᵢ for a total of 2^{N+1} such branches between Tᵢ and Tᵢ₊₁, said i≧N or i≧1;
a first illegal branch of said 2 branches to a state S1 at time Tᵢ₊₁; and
another branch of said 2 branches to the state S1, said another branch selected from the group consisting of a second illegal branch and a paralegal branch.

16. The trellis structure of claim 15, wherein the another branch is the paralegal branch.

17. The trellis structure of claim 16, wherein the paralegal branch is a legal branch.

18. The trellis structure of claim 16, wherein the paralegal branch is a forced legal branch.

19. The trellis structure of claim 18, further comprising:
2 branches to each of the 2^{N} binary states at time Tᵢ₊₂ for a total of 2^{N+1} such branches between Tᵢ₊₁ and Tᵢ₊₂;
an illegal branch of said 2 branches to a state S2A at time Tᵢ₊₂ from the state S1;
a paralegal branch of said 2 branches to the state S2A;
an illegal branch of said 2 branches to a state S2B at time Tᵢ₊₂ from the state S1; and
a paralegal branch of said 2 branches to the state S2B.

20. The trellis structure of claim 15, wherein the another branch is the second illegal branch.

21. The trellis structure of claim 15, wherein the state S1 includes M consecutive transitions, and wherein M is selected from the group consisting of 1, 2 , . . . , and N.

22. The trellis structure of claim 15, wherein N=4.

23. An Illegal Branch Exclusion method for calculating a state metric ST_Z of an output state Z given input states X and Y, the method comprising:
providing a state metric ST_X of the input state X and a branch metric BR_X_Z of a branch X→Z from the input state X to the output state Z;
providing a state metric ST_Y of the input state Y and a branch metric BR_Y_Z of a branch Y→Z from the input state Y to the output state Z, said X→Z and Y→Z are both legal or one of said X→Z and Y→Z is illegal and the other of said X→Z and Y→Z is paralegal;
defining A=ST_X+BR_X_Z, B=ST_Y+BR_Y_Z, and a relational condition selected from the group consisting of A>B and A<B; and
calculating ST_Z such that: if X→Z and Y→Z are both legal then said calculating ST_Z is according to ST_Z=B if the relational condition is true or ST_Z=A if the relational condition is false, if X→Z is illegal then said calculating ST_Z is according to ST_Z=B, if Y→Z is illegal then said calculating ST_Z is according to ST_Z=A.

24. The method of claim 23, wherein the relational condition is A>B.

25. The method of claim 23, wherein the relational condition is A<B.

26. The method of claim 23, said calculating implemented by use of a TVT_M2M2 apparatus.

27. A Large State Metric Value method for calculating a state metric ST_Z of an output state Z given input states X and Y, the method comprising:
providing a state metric ST_X of the input state X and a branch metric BR_X_Z of a branch X→Z from the input state X to the output state Z;
providing a state metric ST_Y of the input state Y and a branch metric BR_Y_Z of a branch Y→Z from the input state Y to the output state Z, said X→Z and Y→Z are both legal or said X→Z and Y→Z are both illegal;
defining A=ST_X+BR_X_Z, B=ST_Y+BR_Y_Z, and a relational condition selected from the group consisting of A>B and A<B; and
calculating ST_Z such that: if X→Z and Y→Z are both legal then said calculating ST_Z is according to ST_Z=B if the relational condition is true or ST_Z=A if the relational condition is false, if X→Z and Y→Z are both illegal then said calculating ST_Z is according to ST_Z=LSMV, said LSMV being positive and sufficiently large if the relational condition is A>B or said LSMV being negative and sufficiently large if the relational condition is A<B.

28. The method of claim 27, wherein the relational condition is A>B.

29. The method of claim 27, wherein the relational condition is A<B.

30. The method of claim 27, said calculating implemented by use of a TVT_M3 apparatus.

31. A TVT_M2M2 apparatus configured to calculate a state metric ST_Z of an output state Z given input states X and Y, comprising:
an adder configured to compute A and B, said A=ST_X+BR_X_Z, said ST_X being a state metric of the input state X, said BR_X_Z being a branch metric of a branch X→Z from the input state X to the output state Z, said B=ST_Y+BR_Y_Z, said ST_Y being a state metric of the input state Y, said BR_Y_Z being a branch metric of a branch Y→Z from the input state Y to the output state Z, said X→Z and Y→Z are both legal or one of said X→Z and Y→Z is illegal and the other of said X→Z and Y→Z is paralegal;
a comparator configured to receive A and B from said adder, said comparator configured to compare A and B to ascertain whether a relational condition is true, said comparator configured to generate a comparator output of 1 if the relational condition is true or to generate the comparator output of 0 if the relational condition is false, said relational condition being selected from the group consisting of A>B and A<B;
a first multiplexor (MUX1) having input ports D0 and D1 and select input SEL1, said D0 configured to receive the comparator output, said D1 configured to receive 0 if said Y→Z is illegal, said D1 configured to receive 1 if said X→Z illegal, said SEL1 configured to be set to 0 if said X→Z and Y→Z are both legal, said SEL1 configured to be set to 1 if one of said X→Z and Y→Z is illegal and the other of said X→Z and Y→Z is paralegal, if SEL1=0 said MUX1 configured to select D0, if SEL1=1 said MUX1 configured to select D1, said MUX1 configured to generate a MUX1 output of what the MUX1 has selected; and
a second multiplexor (MUX2) having input ports E0 and E1 and select input SEL2, said E0 configured to receive A from the adder, said E1 configured to receive B from the adder, set SEL2 configured to receive the MUX1 output, if SEL2=0 then said MUX2 configured to select E0, if SEL2=1 then said MUX2 configured to select E1, said MUX2 configured to generate a MUX2 output of what the MUX2 has selected, said ST_Z=said MUX2 output.

32. The TVT_M2M2 apparatus of claim 31, further comprising a latch configured to receive the MUX2 output.

33. The TVT_M2M2 apparatus of claim 31, wherein the relational condition is A<B.

34. The TVT_M2M2 apparatus of claim 31, wherein the relational condition is A>B.

35. A TVT_M3 apparatus configured to calculate a state metric ST_Z of an output state Z given input states X and Y, comprising:
an adder configured to compute A and B, said A=ST_X+BR_X_Z, said ST_X being a state metric of the input state X, said BR_X→Z being a branch metric of a branch X→Z from the input state X to the output state Z, said B=ST_Y+BR_Y_Z, said ST_Y being a state metric of the input state Y, said BR_Y_Z being a branch metric of a branch Y→Z from the input state Y to the output state Z, said X→Z and Y→Z both legal or said X→Z and Y→Z both illegal;
a comparator configured to receive A and B from said adder, said comparator configured to compare A and B to ascertain whether a relational condition is true, said comparator configured to generate a comparator output of 1 if the relational condition is true or the comparator output of 0 if the relational condition is not true, said relational condition being selected from the group consisting of A>B and A<B;
a multiplexor (MUX) having input ports D0, D1, and D2 and select inputs SEL1 and SEL2, said D0 configured to receive to receive A from the adder, said Dl configured to receive B from the adder; said D2 configured to receive to receive a Large State Metric Value (LSMV), said LSMV being positive and sufficiently large if said relational condition is A>B or said LSMV being negative and sufficiently large if said relational condition is A<B, said SEL1 configured to be set to 0 if said X→Z and Y→Z are both legal, said SEL1 configured to be set to 1 if said X→Z and Y→Z both illegal, said SEL2 configured to receive the comparator output from the comparator, if SEL1=0 then said MUX configured to select D0 if SEL2=0 or to select D1 if SEL2=1, if SEL1=1 then said MUX configured to select D2, said MUX generating a MUX output of what the MUX has selected, said ST_Z=said MUX output.

36. The TVT_M3 apparatus of claim 35, further comprising a latch configured to receive the MUX output.

37. The TVT_M3 apparatus of claim 35, wherein the relational condition is A<B.

38. The TVT_M3 apparatus of claim 35, wherein the relational condition is A>B.
